(19) United States
(12) Patent Application Publication
(10) Pub. No.: US 2006/0138469 A1
(43) Pub. Date: Jun. 29, 2006

(54) Semiconductor device and fabricating method thereof

(76) Inventor: Tae Young Lee, Gyeonggi-do (KR)

Correspondence Address: Song K. Jung;MCKENNA LONG & ALDRIDGE LLP, 1900 K Street, N.W., Washington, DC, 20006, US

(21) Appl. No.: 11/314,414

(22) Filed: Dec. 22, 2005

(30) Foreign Application Priority Data
Dec. 29, 2004 (KR) 10-2004-0114598

(51) Int. Cl. H01L 29/76; H01L 23/48

(52) U.S. Cl. 257/213; 257/760; 257/E23.143

(57) ABSTRACT

A semiconductor device and fabricating method thereof can prevent an electrical characteristic degradation of the semiconductor device when a boarderless type contact is formed. The device may include a transistor on a semiconductor substrate, an oxynitride layer on the semiconductor sustrate,an insulating interlayer on the oxynitride layer, a metal line on the insulating interlayer, contact perforating the insulating interlayer and the oxynitride layer to electrically connect the metal line to the transistor.

This application claims the benefit of Korean Patent Application No. 10-2004-0114598, filed on Dec. 29, 2004, which is hereby incorporated by reference for all purposes as if fully set forth herein.

### BACKGROUND OF THE INVENTION

1. Field of the Invention

The present invention relates to a semiconductor device, and more particularly, to a semiconductor device and fabricating method thereof. Although the present invention is suitable for a wide scope of applications, it is particularly suitable for preventing an electrical characteristic degradation of the semiconductor device when a boarderless type contact is formed.

2. Discussion of the Related Art

Generally, a contact in a semiconductor device enables a selective vertical interconnection between a metal line and a prescribed portion of the semiconductor device formed on a substrate.

For the selective vertical interconnection between the metal line and the prescribed area of the semiconductor device using the contact, a contact hole perforating an insulating interlayer is formed by photolithography. As the insulating interlayer becomes thicker, according to the high degree of semiconductor device integration, and as a width of a contact hole is finely decreased, it becomes more difficult to etch the insulating interlayer by photolithography. Also, an alignment margin is reduced and causes misalignment.

If misalignment is generated when performing photolithography on the insulating interlayer, defects are generated in the semiconductor device and degrade the reliability of the semiconductor.

To accurately connect a contact to a specific area of a semiconductor device, the area of the semiconductor device is typically formed so that it is greater than is required. The area of the semiconductor device that is greater than a substantial size is called a boarder of the contact.

Since the presence of a boarder of a semiconductor device decreases the level of integration that is feasible in a semiconductor device, many efforts have been made to form a boarderless type contact.

A portion of a boarderless type contact may be formed on a substrate to extend to a lateral side of a device isolation area, which separates semiconductor devices from each other electrically. However, if the boarderless type contact extends to the lateral side of the device isolation area, leakage current is generated and degrades electrical characteristics of the semiconductor device.

Thus, when forming a contact hole by etching an insulating interlayer, an etch stop layer of nitride is used to cut off an etch according to an etch selection ratio with respect to the insulating interlayer.

The etch stop layer is provided between a silicide layer and an insulating interlayer formed on a substrate by a general semiconductor device fabricating method. If the etch stop layer of nitride is formed between the silicide layer and the insulating interlayer, electrical characteristics of the semiconductor device are degraded.

For instance, since the nitride applies a strong stress to a neighboring layer, a saturation current or a threshold voltage of the semiconductor device is affected and a malfunction of the semiconductor device is induced.

Moreover, if the nitride layer is formed on the silicide layer, a sheet resistance of the silicide layer is raised and agglomeration of silicide is induced. Hence, electrical characteristics of the semiconductor device are degraded.

Also, a charging characteristic in selectively removing the nitride layer by plasma differs from a charging characteristic in etching the insulating interlayer. Hence, reliability of the semiconductor device is lowered.

### SUMMARY OF THE INVENTION

Accordingly, the present invention is directed to a semiconductor device and fabricating method thereof that substantially obviate one or more problems due to limitations and disadvantages of the related art.

An advantage of the present invention is to provide a semiconductor device and fabricating method thereof, by which an electrical characteristic degradation of the semiconductor device can be prevented when a boarderless type contact is formed.

Additional features and advantages of the invention will be set forth in the description which follows, and will be apparent from the description, or may be learned by practice of the invention. The objectives and other advantages of the invention may be realized and attained by the structure and method particularly pointed out in the written description and claims hereof as well as the appended drawings.

To achieve these and other advantages and in accordance with the purpose of the invention, as embodied and broadly described, a semiconductor device includes a transistor on a semiconductor substrate, an oxynitride layer on the semiconductor substrate including the transistor, an insulating interlayer on the oxynitride layer, a metal line on the insulating interlayer, and a contact perforating the insulating interlayer and the oxynitride layer to electrically connect the metal line to the transistor.

In another aspect of the present invention, a method of fabricating a semiconductor device includes the steps of forming a transistor on a semiconductor substrate, forming an oxynitride layer on the semiconductor substrate including the transistor, forming at least one insulating interlayer on the oxynitride layer, forming a contact hole by selectively etching the at least one insulating interlayer and the oxynitride layer until a prescribed portion of the transistor is exposed, and forming a contact by filling the contact hole with a conductive substance.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiment(s) of the invention and together with the description serve to explain the principles of the invention. In the drawings:

FIGS. 1A to 1D are cross-sectional diagrams of a semiconductor device fabricated by a method according to an exemplary embodiment of the present invention.

### DETAILED DESCRIPTION OF THE INVENTION

Reference will now be made in detail to exemplary embodiments of the present invention, examples of which are illustrated in the accompanying drawings. Wherever possible, the same reference numbers will be used throughout the drawings to refer to the same or similar parts.

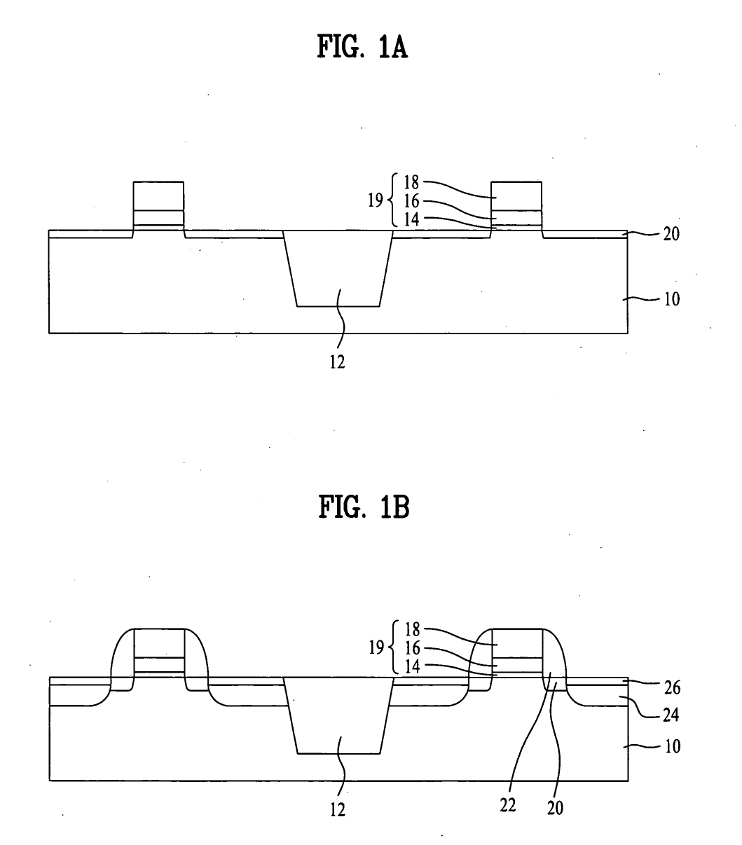

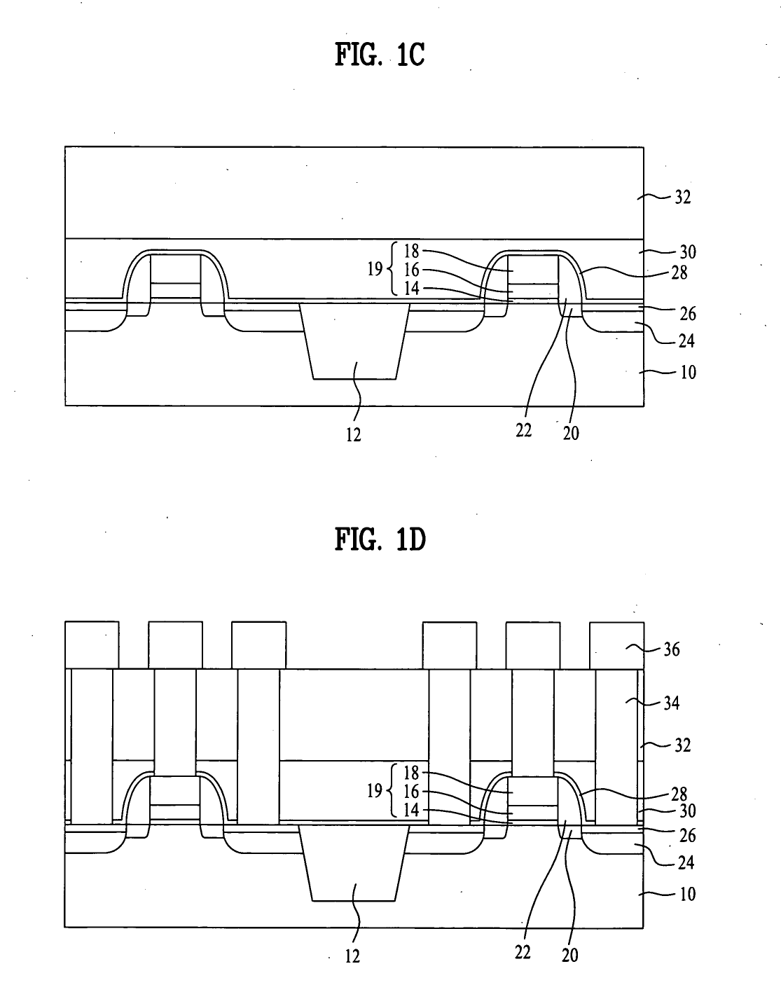

Referring to FIG. 1A, a trench is formed by etching a portion of the semiconductor substrate 10. A device isolating layer 12 is formed by filling the trench with an insulator to electrically isolate a semiconductor device.

A gate insulating layer (not shown) is formed on the substrate 10. A polysilicon layer (not shown) and a silicide layer (not shown) are sequentially stacked on the gate insulating layer. The silicide, polysilicon and gate insulating layers are selectively etched to form a gate electrode 19 including a silicide 18, a polysilicon 16 and a gate insulating layer 14.

Subsequently, LDD (lightly doped drain) regions 20 are formed by lightly implanting impurity ions into the substrate 10 next to both sides of the gate electrode 19, respectively.

Referring to FIG. 1B, an insulating layer (not shown) is deposited on the substrate 10 including the gate electrode 19 and is then selectively etched to form a spacer 22 on each sidewall of the gate electrode 19. Source/drain regions 24 are formed in the substrate 10 by heavily implanting impurity ions into the substrate 10 using the gate electrode 19 and the spacer 22 as a mask.

A metal having a high melting point such as Ti, Co, W, etc. is deposited on the substrate 10 having the source/drain regions 24 and is then annealed to form a silicide layer 26 on the source/drain regions 24 by silicidation. The metal that fails to participate in the silicidation is subsequently removed.

In an exemplary embodiment of the present invention, the silicide 18 of the gate electrode 19 and the silicide layer 26 on the source/drain regions 24 are formed by separate processes. Alternatively, the silicide 18 of the gate electrode 19 and the silicide layer 26 on the source/drain regions 24 can be simultaneously formed by salicidation.

Referring to FIG. 1C, an oxynitride layer 28 is formed as an etch stop layer on the substrate 10. The oxynitride layer 28 can be formed by depositing an oxygen-rich oxynitride film having an oxygen content greater than a nitrogen content at approximately 300 to 400° C. by PECVD (plasma enhanced chemical vapor deposition). This prevented the agglomeration of the silicide 18 or the silicide layer 26 at the temperature above 400° C. Optimally, when deposition occurs at 350° C., the agglomeration of silicide can be minimized.

Subsequently, first and second insulating interlayers (poly metal dielectric: PMD) 30 and 32 may be formed of BPSG (borophospho silicate glass) or PSG (phospho silicate glass) on the oxynitride layer 28. The second insulating interlayer 32 is then planarized by CMP (chemical mechanical polishing) if necessary. In FIG. 1C, the first and second insulating layers 30 and 32 are formed. Alternatively, the first and second insulating layers 30 and 32 can be replaced by one insulating interlayer or at least three insulating interlayers. Optionally, a buffer layer (not shown) can be formed on the planarized second insulating interlayer 32 to compensate for scratches caused by the CMP.

The oxynitride layer 28 has a sufficient etch selection ratio with respect to the first or second insulating interlayer 30 or 32 in an RIE (reactive ion etch) process. Hence, the oxynitride layer 28 can play a role as an etch stop layer in forming a contact hole by etching the second and first insulating interlayers 32 and 30 by RIE.

Subsequently, a contact hole exposing the silicide layer 18 of the gate electrode and contact holes exposing the silicide layer 26 on the source/drain regions 20 are formed by selectively etching the second insulating layer 32, the first insulating layer 30 and the oxynitride/etch stop layer 28. The second and first insulating interlayers 32 and 30 are selectively etched by performing RIE as a first etch until surfaces of the oxynitride layer 28 are exposed. After completion of the first etch, the exposed portions of the oxynitride layer 28 are removed by a second etch. Hence, the contact holes perforating the second insulating interlayer 32, the first insulating interlayer 30 and the oxynitride layer 28 are formed to reach the silicide layers 18 and 26, respectively.

Referring to FIG. 1D, each of the contact holes is filled with a conductive material to form a contact plug 34. A metal line material is deposited on the second insulating interlayer 32 including the contact plug 34. The metal line material is then patterned to form a metal line 36 electrically connected to the corresponding contact plug 34.

Accordingly, the present invention provides the following effects.

When a boarderless type contact is formed by etching the insulating interlayer, the present invention provides an etch stop layer, which may be formed of oxynitride layer. Hence, the present invention prevents electrical characteristic degradation of the semiconductor device.

In particular, the etch stop layer, which may be made of oxynitride, has a stress, which is applied to a neighboring layer. This stress is less than that of the related art nitride layer. Hence, the etch stop layer, which may be made of oxynitride, minimizes an influence of a saturation current or a threshold voltage of the semiconductor device, thereby preventing a malfunction of the semiconductor device.

Also, by forming the etch stop layer, which may be made of oxynitride, at about 350° C., the sheet resistance increment and agglomeration of a neighboring silicide layer can be prevented. Hence, the present invention prevents electrical characteristic degradation of the semiconductor device.

Also, by removing the etch stop layer, which may be made of oxynitride, based on the etch selectivity ratio with respect to the insulating interlayer, the present invention can prevent a reduction in reliability of the semiconductor device that would otherwise occur when a related art nitride layer is removed by plasma etch.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A semiconductor device comprising:
a transistor on a semiconductor substrate;
an oxynitride layer on the semiconductor substrate including the transistor;
an insulating interlayer on the oxynitride layer;
a metal line on the insulating interlayer; and
a contact perforating the insulating interlayer and the oxynitride layer to electrically connect the metal line to the transistor.

2. The semiconductor device of claim 1, wherein the oxynitride layer has an oxygen content greater than a nitrogen content.

3. The semiconductor device of claim 1, wherein the insulating interlayer comprises a material selected from the group consisting of oxide, BPSG (borophospho silicate glass) and PSG (phospho silicate glass).

4. The semiconductor device of claim 1, wherein a surface of the insulating interlayer is planarized by CMP (chemical mechanical polishing).

5. The semiconductor device of claim 4, further comprising a buffer layer on the planarized surface of the insulating interlayer to compensate for scratches caused by the CMP.

6. A method of fabricating a semiconductor device, comprising the steps of:
forming a transistor on a semiconductor substrate;
forming an oxynitride layer on the semiconductor substrate including the transistor;
forming at least one insulating interlayer on the oxynitride layer;
forming a contact hole by selectively etching the at least one insulating interlayer and the oxynitride layer until a prescribed portion of the transistor is exposed; and
forming a contact by filling the contact hole with a conductive substance.

7. The method of claim 6, wherein the oxynitride layer has an oxygen content greater than a nitrogen content.

8. The method of claim 6, wherein forming an oxynitride layer is performed by PECVD (plasma enhanced chemical vapor deposition).

9. The method of claim 8, wherein the PECVD is performed at approximately 300 to 400° C.

10. The method of claim 8, wherein the PECVD is performed at 350° C.

11. The method of claim 6, wherein the insulating interlayer comprises a material selected from the group consisting of oxide, BPSG (borophospho silicate glass) and PSG (phospho silicate glass).

12. The method of claim 6, further comprising the step of planarizing the at least one insulating interlayer by chemical mechanical polishing.

13. The method of claim 12, further comprising the step of forming a buffer layer on the planarized insulating interlayer.
